(19) United States
(12) Patent Application Publication
(10) Pub. No.: US 2018/0155821 A1
(43) Pub. Date: Jun. 7, 2018

(54) Magnetron Sputtering Apparatus

(71) Applicant: ULVAC, INC., Kanagawa (JP)

(72) Inventors: Shinya Nakamura, Kanagawa (JP); Yoshinori Fujii, Kanagawa (JP)

(73) Assignee: ULVAC, INC., Kanagawa (JP)

(21) Appl. No.: 15/571,574

(22) PCT Filed: May 11, 2016
(86) PCT No.: PCT/JP2016/002308

§ 371 Date: Nov. 3, 2017

(30) Foreign Application Priority Data
May 22, 2015 (JP) 2015-104441

(51) Int. Cl. C23C 14/35; C23C 14/34; H01J 37/34

(52) U.S. Cl. CPC C23C 14/35; C23C 14/3407; H01J 37/321; H01J 37/3455; H01J 37/347; H01J 37/3408

(57) ABSTRACT

The magnetron sputtering apparatus SM has: a vacuum chamber; and a cathode unit C detachably mounted on the vacuum chamber. The cathode unit has: a target which is disposed to face an inside of the vacuum chamber; and a magnet unit disposed to that side of the target which is opposite to a sputtering surface, thereby generating a leakage magnetic field on a side of the sputtering surface. The sputtering apparatus SM of this invention, having the above-mentioned arrangement has a drive source for driving the magnet unit to rotate with a target center serving as a center of rotation while the target is sputtered to form a film on a to-be-processed substrate. Auxiliary magnet units which cause a leakage magnetic field to function on the inside of the vacuum chamber are locally disposed on an external wall of the vacuum chamber or of a housing H of the cathode unit.

### TECHNICAL FIELD

The present invention relates to a magnetron sputtering apparatus.

### BACKGROUND ART

In the process of manufacturing the next generation of semiconductor devices such as NAND type flash memories, a magnetron sputtering apparatus is used in order to form electrically insulating films such as aluminum oxide films and the like. As the magnetron sputtering apparatus, there is known one comprising: a vacuum chamber; and a cathode unit detachably mounted on the vacuum chamber. The cathode unit comprises: a target which is disposed to face an inside of the vacuum chamber; and a magnet unit disposed on that side of the target which is opposite to a sputtering surface so as to generate a leakage magnetic field on a side of the sputtering surface. There is also provided a drive source for driving to rotate the magnet unit to rotate with a target center serving as a center of rotation, while the target is sputtered to form a film on a substrate that is to be processed (to-be-processed substrate) by being disposed in the vacuum chamber so as to lie opposite to the target (see, e.g., Patent Document 1).

In the film forming by using this kind of magnetron sputtering apparatus, it is known that, attributable to the position of an exhaust port or the position of a gas introduction port that is disposed in the vacuum chamber, deviation may occur in the film thickness distribution of the thin film that is formed on the to-be-processed substrate. In the next generation of semiconductor devices, the in-plane film thickness distribution is required to be controlled, e.g., under 1%. In order to meet the requirements, it becomes important how the deviation in the film thickness distribution shall be restrained. In this case, it is conceivable to arrange the magnets of the magnet unit in a manner movable in one direction. There is, however, a problem in that the apparatus arrangement becomes complicated.

### PRIOR ART DOCUMENT

### Patent Document

Patent document 1: JP-A-1993-209268

### SUMMARY OF THE INVENTION

### Problems to be Solved by the Invention

On the basis of the above finding, this invention has a problem of providing a magnetron sputtering apparatus in which the deviation in the film thickness distribution can be effectively restrained with a simple arrangement.

### Means for Solving the Problems

In order to solve the above problem, the magnetron sputtering apparatus according to this invention comprises: a vacuum chamber; a cathode unit detachably mounted on the vacuum chamber. The cathode unit comprises: a target disposed to face an inside of the vacuum chamber; and a magnet unit disposed to that side of the target which is opposite to a sputtering surface so as to generate a leakage magnetic field on a side of the sputtering surface. The sputtering apparatus further comprises a drive source for driving the magnet unit to rotate with a target center serving as a center of rotation while the target is sputtered to form a film on a to-be-processed substrate disposed in the vacuum chamber in a manner to lie opposite to the target. Auxiliary magnet units for causing the leakage magnetic field to act on the inside of the vacuum chamber are locally disposed on an external wall of one of the vacuum chamber and a housing of the cathode unit. The auxiliary magnet units are disposed to coincide with a direction of that deviation in film thickness distribution which occurs when the film is formed on the to-be-processed substrate.

According to this invention, due to the function of the leakage magnetic field that is generated by the auxiliary magnet units, the deviation in the film thickness distribution of the thin film formed on the to-be-processed substrate can be effectively restrained and, consequently, the in-plane film thickness distribution can be improved. In addition, since there is no need of providing the apparatus with a complicated mechanism for moving the magnet units in one direction, the improvement can be materialized in a simple arrangement.

By the way, in case the target is made of an electrically insulating material, and this target of electrically insulating material is disposed in the cathode unit in a state of being bonded to a backing plate having disposed therein a coolant circulation passage, and in case the target is sputtered by charging RF power to thereby form a film, it has been found that the film thickness becomes small in a portion in which the coolant is discharged out of the coolant circulation passage in the backing plate. We have obtained a finding that this is attributable to the fact that the RF power is consumed in the neighborhood of the coolant flow outlet in which the cooling water is discharged from the coolant circulation passage and, as a consequence, that the plasma impedance becomes locally low.

As a solution, in this invention by disposing the auxiliary magnet units so as to step over a point of intersection of a line that extends from the center of the target through the coolant flow outlet and the external wall of the vacuum chamber, the plasma impedance in the neighborhood of the coolant flow outlet was increased, so that the deviation in the film thickness distribution can be effectively restrained. According to the experiments made by the inventors of this invention, it has been confirmed that the in-plane film thickness distribution could be controlled under 0.6%.

### BRIEF DESCRIPTION OF THE DRAWINGS

FIG. 1 is a schematic sectional view showing the magnetron sputtering apparatus according to an embodiment of this invention.

FIG. 2 is a schematic sectional view taken along the line II-II in FIG. 1.

FIGS. 3(a) and 3(b) are illustrations showing the results of experiments to confirm the effects of this invention.

### MODES FOR CARRYING OUT THE INVENTION

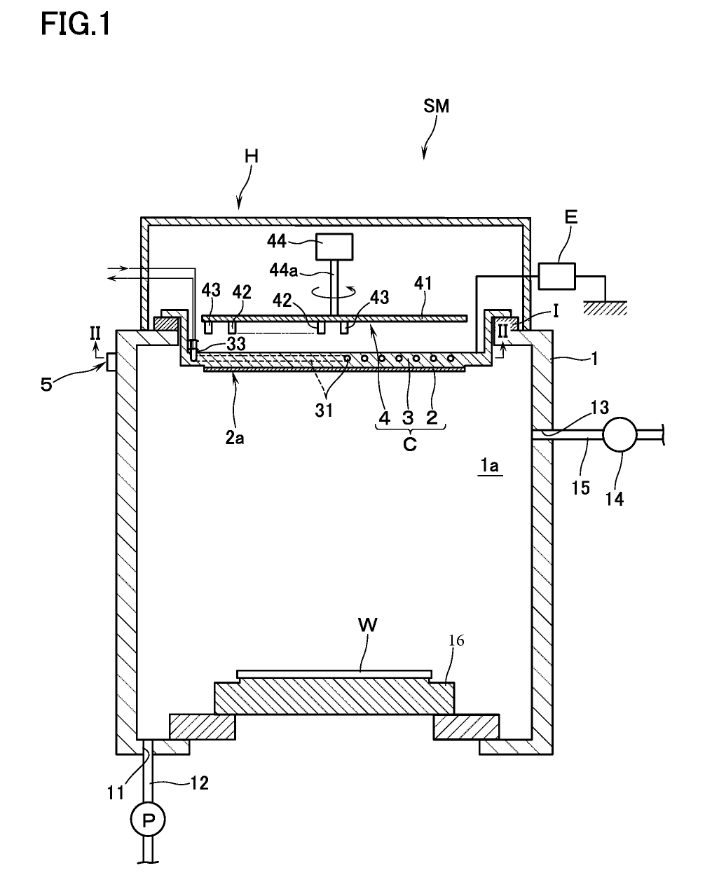

With reference to the drawings a description will now be made of a magnetron sputtering apparatus according to an embodiment of this invention. In the following, description will be made with FIG. 1 as a standard in which the ceiling portion side of the vacuum chamber 1 is referred to as “upper” and the bottom portion side thereof is referred to as “lower.”

As shown in FIG. 1, the magnetron sputtering apparatus SM has a vacuum chamber 1 which defines a processing chamber 1a. An exhaust port 11 is disposed at the bottom portion of the vacuum chamber 1. This exhaust port 11 is connected, through an exhaust pipe 12, to a vacuum pump P which is made up of a turbo molecular pump, rotary pump, and the like. It is thus so arranged that the processing chamber 1a can be evacuated down to a predetermined pressure (e.g., 1×10⁻⁵ Pa). A side wall of the vacuum chamber 1 is provided with a gas introduction port 13. To this gas introduction port 13 is connected a gas pipe 15 that is communicated with a gas source (not illustrated) and has interposed therein a mass flow controller 14. It is thus so arranged that a sputtering gas made up of rare gas such as Ar and the like can be introduced into the processing chamber 1a at a predetermined flow amount.

The bottom portion of the vacuum chamber 1 has disposed therein a substrate stage 16 so as to lie opposite to a target (to be described hereinafter). The substrate stage 16 has a known electrostatic chuck (not illustrated). By charging a predetermined voltage to an electrode of the electrostatic chuck, a substrate W that is to be processed is arranged to be held by suction on the substrate stage 16 with the film-forming surface lying upward.

The ceiling portion of the vacuum chamber 1 is provided with a cathode unit C detachably, i.e., in a manner attachable to, and detachable from, the ceiling portion. The cathode unit C has: a target 2 which is disposed to face the inside of the vacuum chamber 1 (processing chamber 1a); a backing plate 3 which is bonded, through a bonding material such as indium, tin, and the like, to that surface of the target 2 which lies opposite to the sputtering surface 2a; and a magnet unit 4 which is disposed on that side of the target 2 which lies opposite to the sputtering surface 2a, thereby generating a leakage magnetic field on the side of the sputtering surface 2a. The backing plate 3 and the magnet unit 4 are enclosed by the housing H. The target 2 is made of an electrically insulating material such as aluminum oxide (Al₂O₃) and the like that is appropriately selected depending on the composition of the thin film that is going to be formed, and is manufactured into, e.g., a circle as seen from top (plan view) by using a known method. The target 2 has connected thereto an output from a RF power supply as the sputtering power source E, and the RF power is charged during sputtering. The backing plate 3 is made of metal such as Cu and the like that has good heat conduction. The backing plate has disposed inside thereof a coolant circulation passage 31, and also the upper wall thereof has disposed therein a coolant inlet 32 and a coolant outlet 33. It is thus so arranged that a coolant (e.g., cooling water) that is supplied from a chiller (not illustrated) is supplied from the coolant inlet 32 to the coolant circulation passage 31; and that, by discharging the coolant that has circulated through the coolant circulation passage 31 out of the coolant outlet 33, the target 2 can be cooled through heat exchanging with the coolant. The magnet unit 4 has: a yoke 41; a plurality of first magnets 42 of the same magnetization that are disposed side by side with each other in an annular manner on the lower surface of the yoke 41; and a plurality of second magnets 43 of the same magnetization as the first magnets 42 that are disposed side by side in an annular manner so as to enclose the circumference of the first magnets 42. To the upper surface of the yoke 41 is connected a drive shaft 44a of the drive source 44. It is thus so arranged that, while the target 2 is sputtered to thereby form a film, the magnet unit 4 can be driven for rotation with the center of the target 2 serving as the center of rotation.

The above-mentioned magnetron sputtering apparatus SM has a known control means provided with a microcomputer, a sequencer, and the like. It is thus so arranged that an overall control can be made over the operation of the mass-flow controller 10, the operation of the evacuating means P, the driving of the drive source 44, the driving of the chiller, and the like. A description will herein-below be made of a method of sputtering, based on an example of forming an aluminum oxide film using the above-mentioned sputtering apparatus SM.

The vacuum chamber 1 in which a target 2 of aluminum oxide is disposed is evacuated to a predetermined vacuum degree (e.g., 1×10⁻⁵ Pa). A substrate W is transferred by a transfer robot (not illustrated) into the vacuum chamber 1, and the substrate W is handed over into the substrate stage 2 for further electrostatic suction. Then, argon gas which is a sputtering gas is introduced at a flow rate of, e.g., 150˜250 sccm (the pressure inside the vacuum chamber 1 at this time is 2˜4 Pa). By charging RF power (e.g., 13.56 MHz, 4 kW) from the sputtering power source E to the target 2, plasma is formed inside the vacuum chamber 1. According to these operations, the sputtering surface 2a of the target 2 is sputtered, and the splashed sputtering particles are caused to get adhered to, and deposited on, the surface of the substrate W, thereby forming an aluminum oxide film.

It is to be noted here that the positions of the first and the second magnets 42, 43 of the magnet unit 4 are designed so that the in-plane film thickness distribution of an aluminum oxide film that is formed on the to-be-processed substrate becomes good. It is, however, known that, due to the position of the exhaust port 11 or the position of the gas introduction port 13, deviation occurs in the film thickness distribution of the thin film that is formed on the to-be-processed substrate W. According to this embodiment, the film thickness became smaller at the portion of the coolant outlet 33 which discharges the coolant from the coolant circulation passage 31 of the backing plate 3. As a result, it has been found that a deviation in the film thickness distribution occurred.

As a solution, according to this embodiment, auxiliary magnet units were locally disposed on an external wall of the vacuum chamber 1 in a manner to coincide with the direction of the deviation in the film thickness distribution, i.e., in a manner to step over the point of intersection Cp of a line that extends from the center of the target 2, passing through the coolant outlet 33, and the external wall of the vacuum chamber 1. The auxiliary magnet units 5 can be constituted by a plurality of (4 pieces in this embodiment) magnets 51 arranged side by side with one another in the circumferential direction. By the way, in order to limit the scope of controlling the film thickness, and make the magnetic field to be closed magnetic field that is not the divergent magnetic field, the plurality of magnets 51 shall preferably be disposed so as to form respective pairs.

According to the embodiment that has been described so far, by the function of the leakage magnetic field that is generated inside the vacuum chamber 1 by the auxiliary magnet units 5, the plasma impedance in the neighborhood of the coolant outlet will be increased, and the deviation in the film thickness distribution can be effectively restrained. As a result, the in-plane film thickness distribution can be improved. In addition, without the necessity of disposing a complicated mechanism of making the magnet unit 4 movable in one direction, the above object can be materialized with a simple arrangement in the form of auxiliary magnet units. The increase in the equipment cost can advantageously be refrained.

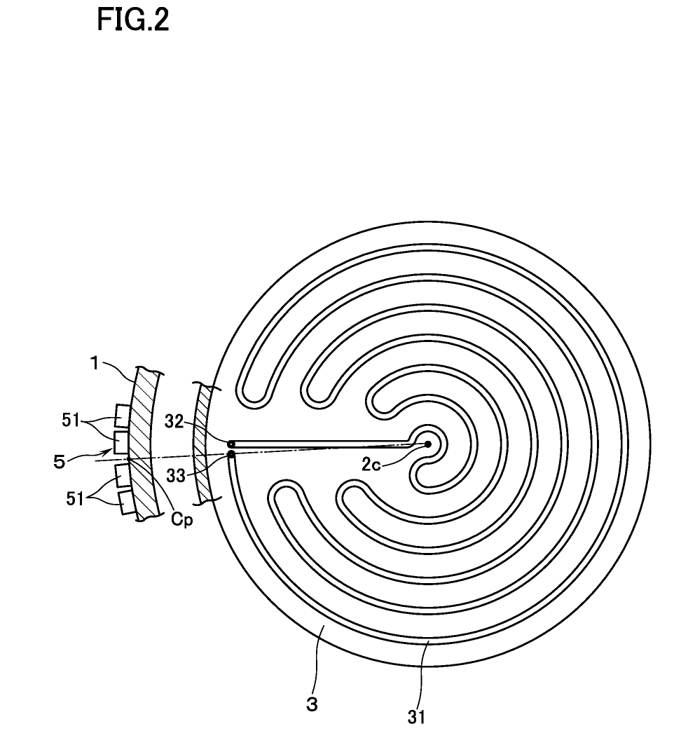

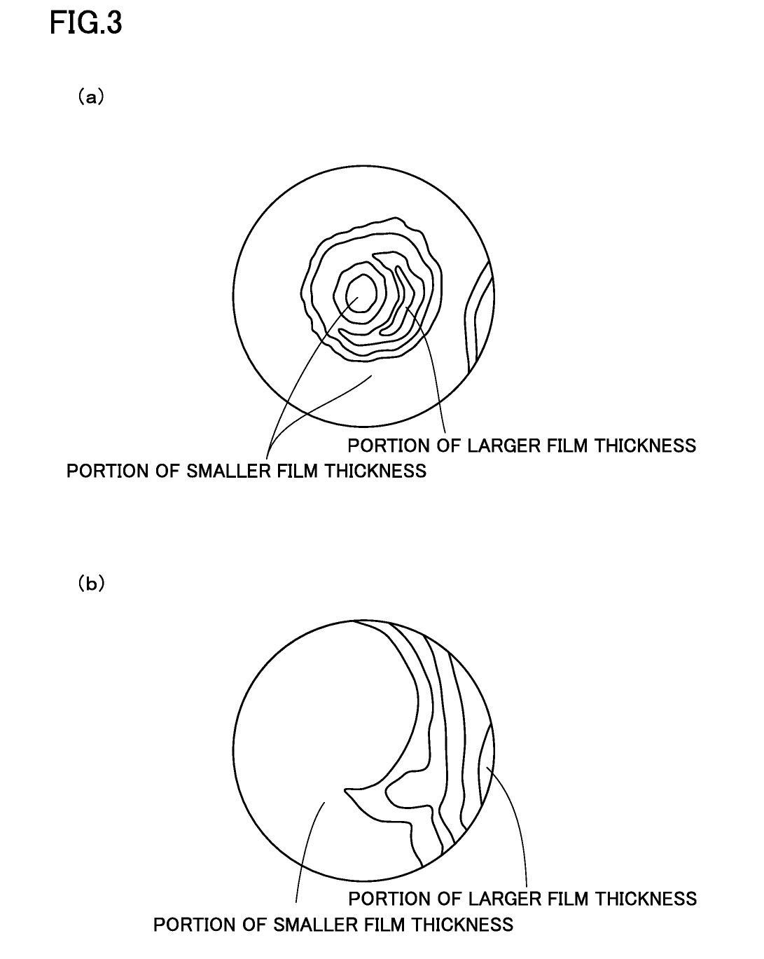

Next, in order to confirm the above effects, the following experiment was carried out by using the above-mentioned magnetron sputtering apparatus SM. In the experiment of this invention, a silicon substrate of 300 mm Φ (in diameter) was used as the to-be-processed substrate W. As the target 2 of the cathode unit C, one made of an aluminum oxide of 400 mm Φ was used. After having assembled this cathode unit C, four magnets 51 of the auxiliary magnet units 5 were disposed, as shown in FIG. 2, on the external wall of the vacuum chamber 1 in a manner to step over the point of intersection Cp. Then, after having set the to-be-processed substrate W on the substrate stage 16 in the vacuum chamber 1, the magnet unit 4 was rotated at a rotational speed of 40 rpm. Also, argon gas was introduced into the vacuum chamber 1 at a flow rate of 200 sccm (the pressure inside the vacuum chamber 1 at this time was 3 Pa). RF power of 13.56 MHz was charged in an amount of 4 kW to the target 2 to thereby generate plasma and, by means of sputtering, an aluminum oxide film was formed on the to-be-processed substrate W. An average film thickness of the aluminum oxide film thus formed was 45.61 nm, the in-plane film thickness distribution (σ) was 0.55%. As shown in FIG. 3(a), it has been confirmed that the portions having equal film thicknesses that are connected together by lines within the in-plane of the substrate can be seen in substantially concentric circles, whereby the deviation in the in-plane film thickness distribution has been restrained. It is to be noted that the direction shown in FIG. 3(a) corresponds to the direction shown in FIG. 2.

Comparative experiment was carried out for comparison with the above-mentioned experiment of this invention. In the comparative experiment, an aluminum oxide film was formed under the similar terms as those of this invention except for the point that the auxiliary magnet units 5 were not disposed in the comparative experiment. An average film thickness of the aluminum oxide film that was formed was 46.16 nm, and the in-plane film thickness distribution (σ) was 1.19%. As shown in FIG. 3(b), the deviation in the film thickness deviation has been confirmed: that the film thickness was thin at the left portion corresponding to the coolant outlet 33; and that the further goes to the right, the thicker becomes the film thickness. According to the above experiment of this invention and the comparative experiment, it has been confirmed that: by locally disposing the auxiliary magnet units 5 on the external wall of the vacuum chamber 1, the deviation in the film thickness distribution can be restrained; and further that the in-plane film thickness distribution can largely be improved to under 0.6%.

Description has so far been made of an embodiment of this invention. However, this invention shall not be limited to the above. In the above embodiment, a description has been made of an example in which the auxiliary magnets 5 were disposed on the external wall of the vacuum chamber 1, but they may alternatively be disposed on the external wall of the housing H in a manner to coincide with the direction of deviation in film thickness distribution. Further, in the above-mentioned embodiment, the auxiliary magnet units 5 were constituted by four pieces of magnets 51. However, the number of the magnets 51 may appropriately be set depending on the range in which the leakage magnetic field is to be functioned.

Further, in the above-mentioned embodiment, aluminum oxide was explained as an example of material in which the target 2 is made. However, without being limited to the above, the electrically insulating material such as MgO, SiC, SiN and the like may be selected, and the metal of Ti, Cu, Al and the like may be selected. In case the target 2 made of metal is used, known DC power source may be used as the sputtering power source E.

### DESCRIPTION OF REFERENCE MARKS

SM magnetron sputtering apparatus
C cathode unit
Cp point of intersection of a line which extends from the center 2c of the target, through a coolant outlet 33, and the external wall of the vacuum chamber 1
H housing
W substrate to be processed (to-be-processed substrate)
1 vacuum chamber
2 target
2a sputtering surface
2c center of target 2
3 backing plate
31 coolant circulation passage
32 coolant inlet
33 coolant outlet
4 magnet unit
5 auxiliary magnet unit

What is claimed is:

1. A magnetron sputtering apparatus comprising:
a vacuum chamber;
a cathode unit detachably mounted on the vacuum chamber, the cathode unit comprising: a target disposed to face an inside of the vacuum chamber; and a magnet unit disposed to that side of the target which is opposite to a sputtering surface so as to generate a leakage magnetic field on a side of the sputtering surface;
a drive source for driving the magnet unit to rotate with a target center serving as a center of rotation while the target is sputtered to form a film on a to-be-processed substrate disposed in the vacuum chamber in a manner to lie opposite to the target,
wherein auxiliary magnet units for causing the leakage magnetic field to act on the inside of the vacuum chamber are locally disposed on an external wall of one of the vacuum chamber and a housing of the cathode unit, the auxiliary magnet units being disposed to coincide with a direction of that deviation in film thickness distribution which occurs when the film is formed on the to-be-processed substrate.

2. The magnetron sputtering apparatus according to claim 1,
wherein the target is made of an electrically insulating material, and the target is disposed in the cathode unit in a state of being bonded to a backing plate, the backing plate having disposed therein a coolant circulation passage, and
while the target is sputtered by charging RF power to thereby form a film, the target is cooled, through heat exchanging with a coolant, by supplying the coolant through a coolant circulation passage from a coolant flow inlet disposed in an upper wall of the backing plate and by discharging the coolant out of a coolant flow outlet disposed in the upper wall of the backing plate,
wherein the auxiliary magnet units are disposed to step over a point of intersection of a line that extends from the center of the target through the coolant flow outlet and the external wall of the vacuum chamber.
